(19) United States
(12) Patent Application Publication
(10) Pub. No.: US 2025/0385681 A1
(43) Pub. Date: Dec. 18, 2025

(54) COMPENSATION OF ANALOG-TO-DIGITAL CONVERTER (ADC) GAIN ERROR

(71) Applicant: Microchip Technology Incorporated, Chandler, AZ (US)

(72) Inventors: Jason M. Sachs, Chandler, AZ (US); William Henry Stewart, San Tan Valley, AZ (US)

(21) Appl. No.: 19/242,679

(22) Filed: Jun. 18, 2025

Related U.S. Application Data
(60) Provisional application No. 63/661,237, filed on Jun. 18, 2024.

(51) Int. Cl. H03M 1/06; H03M 1/10; H03M 3/00

(52) U.S. Cl. CPC H03M 1/0607; H03M 1/1019; H03M 3/354

(57) ABSTRACT

A method may include generating, via a sigma-delta DAC, a series of analog voltage levels that are equally spaced across a selected portion of ADC range; measuring, via the ADC, the series of analog voltages levels generated via the sigma-delta DAC; determining an error of a system at least partially based on a comparison of ADC output values and expected ADC output values, the system including the sigma-delta DAC and the ADC; modeling the error of the system using a combination of piecewise linear basis functions representing different types of errors or offsets; and determining a gain error of the ADC at least partially based on a coefficient of a linear basis function corresponding to the gain error of the ADC, the linear basis function one of the piecewise linear basis functions used to model the error of the system.

### CROSS-REFERENCE TO RELATED APPLICATION

This application claims the benefit under 35 U.S.C. § 119(e) of U.S. Provisional Patent Application Ser. No. 63/661,237, filed Jun. 18, 2024, the disclosure of which is hereby incorporated herein in its entirety by this reference.

### BACKGROUND

Analog-to-digital converters (ADCs) convert analog signals into digital data that can be processed by digital system. ADCs are used in a wide range of applications and a variety of operational contexts. Ensuring the accuracy and reliability of the conversion process is important for maintaining the proportional relationship between the input signal and the digital output.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram depicting a system to determine gain-error compensation for an ADC, in accordance with one or more examples.

FIG. 2 is a block diagram depicting an apparatus for determining gain-error compensation in accordance with one or more examples.

FIG. 3 is a block diagram depicting a system that compensates ADC output based on offset or gain error determined in accordance with one or more examples.

FIG. 4 is a flow diagram depicting a process to determine a gain-error compensation in accordance with one or more examples.

FIG. 5 is a flow diagram depicting a process to generate the voltage levels that are equally spaced across a selected portion of the ADC range, in accordance with one or more examples.

FIG. 6 is a flow diagram depicting a process to determine gain error of an ADC in accordance with one or more examples.

FIG. 7 is a block diagram of circuitry that, in some examples, may be used to implement various functions, operations, acts, processes, or methods disclosed herein.

FIG. 8 is a schematic diagram depicting a system in accordance with one or more examples.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description, the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

In this description, the term “space” and derivatives thereof may be used to indicate an interval or distance between two or more elements. When elements are described as being “equally spaced” or having “equal spacing” then the spacing between the elements may be entirely uniform or there may be some variation in the spacing between the elements. In contrast, when elements are described as being “exactly equally spaced” or having “exactly equal spacing” then the spacing between the elements is uniform and there is no variation in the spacing between the elements.

Gain error of an analog-to-digital (ADC) converter is the difference between the actual slope of ADC transfer function and an ideal (e.g., target, without limitation) slope of the ADC transfer function. Quantification of the difference between actual slope and ideal slope is often normalized to the full range of the ADC (ADC range) and expressed as a ratio (e.g., fractional or integer multiple, without limitation) or other dimensionless quantity that is easy to compare across different ADCs. Gain error is different than offset error, which is the difference between actual and ideal (e.g., target, without limitation) output of the ADC when the input is zero or a minimum value. Gain error is also different than full scale error, which is the total difference of the ADC's output from the ideal output over its entire input range and includes both offset error and gain error. Gain error manifests as a proportional scaling discrepancy between actual ADC output and 1, which can significantly degrade the accuracy of measurements of an ADC and is particularly problematic in applications requiring high precision.

In precision analog-to-digital conversion systems, accurately quantifying and compensating for gain error is critical to ensuring the fidelity of digital representations of analog signals. ADC modules in microcontrollers may support multiple input channels that are fed to the same converter hardware. Gain error and offset of a respective ADC module are experienced by every input channel since they share the same analog converter circuitry.

Gain error and offset error can be measured and compensated. Measurement of gain error requires conversion of two or more reference voltages. To accurately determine and compensate for gain error, the gain error exhibited by the reference voltages used by the ADC should be minimized or carefully managed. Any gain error in the reference voltages impacts the post-compensation accuracy.

Traditional methods of gain-error compensation often fall short in addressing the non-linearities and variances inherent in an ADC's operating range.

One or more examples relate, generally, to using a digital-to-analog converter (DAC) with known, low gain error and known (e.g., modeled, without limitation) integral non-linearity (INL) characteristics (e.g., a sigma-delta DAC, without limitation) to generate a series of equally spaced analog voltage levels, which are then sampled by the ADC. The ADC's digital output is compared with expected values (e.g., a set of predetermined values, without limitation) and error data is accumulated across the ADC's range (e.g., across different segments of the ADC's range, without limitation). The error data is modeled using piecewise linear basis functions, which represent (e.g., accurately represent, without limitation) various types of errors including, without limitation, gain error (e.g., ADC gain error, without limitation). One or more coefficients are derived for these basis functions (e.g., via a least-squares analysis, without limitation), allowing precise quantification of the various types of error, including, without limitation, the gain error of the ADC. The gain error of the ADC is determined as a specific coefficient. In one or more examples, the determined gain error may be used to determine effective calibration and compensation for the ADC (e.g., the actual ADC or design thereof, without limitation) that was analyzed or a different, similar, ADC (e.g., similar to the actual ADC or design thereof, without limitation).

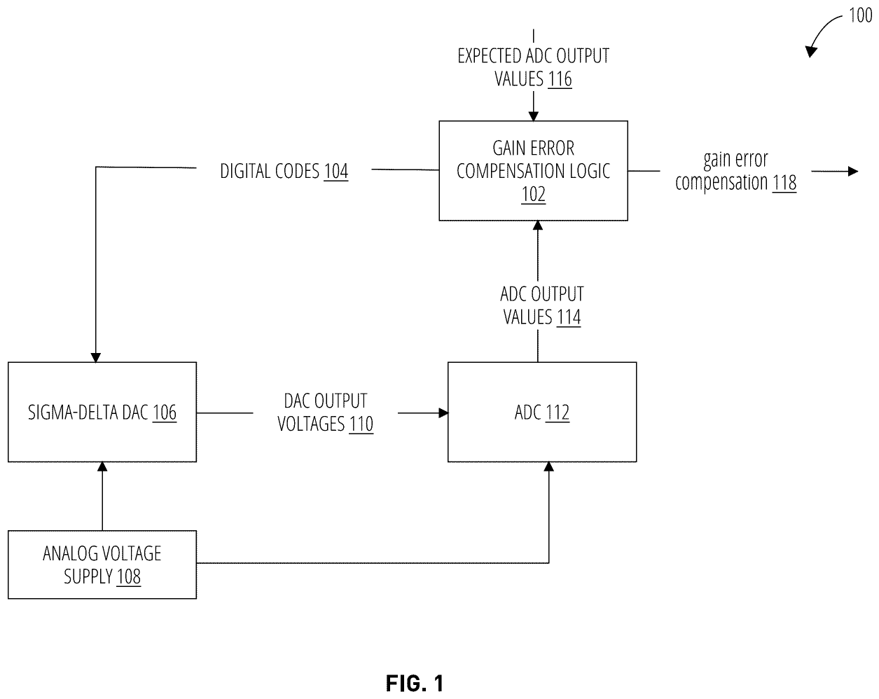

FIG. 1 is a block diagram depicting a system 100 to determine gain-error compensation for an ADC, in accordance with one or more examples.

System 100 includes a Sigma-Delta DAC 106, an analog voltage supply 108, an ADC 112, and a gain-error compensation logic 102. It should be appreciated that in various examples, the sigma-delta DAC 106 and the ADC 112 may be monolithically integrated on the same mixed-signal semiconductor die, thereby reducing interconnect parasitics and ensuring both converters share identical process, voltage, and temperature conditions. Alternatively, in other examples, the DAC 106 and ADC 112 may reside on separate dice or packages—for example, the DAC 106 on a system-on-chip and the ADC 112 in a companion sensor interface device—while still employing the calibration and gain-error-compensation techniques discussed herein.

System 100 determines a gain-error compensation that may be applied to an ADC to manage gain error, as discussed below. In one or more examples, system 100 converts equally spaced DAC output voltages with a target ADC (i.e., the ADC for which gain-error compensation is being determined). System 100 uses the ADC output values to determine the gain-error compensation, as discussed below. A sigma-delta DAC may be controlled to generate the equally spaced DAC output voltages. The input to the sigma-delta DAC is a series of digital codes corresponding to expected voltage levels DAC output voltages. In one or more examples, the digital codes and the expected voltage levels of the DAC output voltages may be chosen to cover most of the ADC range, but do not include upper and lower boundary regions of the ADC range. These upper and lower boundary regions of the ADC range may correspond to regions of increased error at the edges of the ranges of operation of either the ADC, DAC, or other analog circuitry (e.g., op-amps, without limitation), without limitation. Alternatively, in one or more examples, the digital codes and the expected voltage levels of the DAC output voltages or may be chosen to cover the full ADC range, including upper and lower bounds of the ADC range.

Exactly equal spacing of DAC output voltages reduces computational complexity as compared to non-equal spacing (some variation in spacing, nonuniform spacing). Effects of having variation in spacing of DAC output voltages may be acceptable depending on specific operating conditions or requirements. In some instances, an available interval of counts (DAC counts) may not evenly divide between a desired number of sub-intervals. As a non-limiting example, a sub-interval (the spacing) of 64 counts does not divide evenly into an interval of 4000 counts. In one or more examples, effects of variation in spacing of DAC output voltages may be managed via specific hardware.

Gain-error compensation logic 102 is a digital logic block or firmware that processes the ADC output values, comprising ADC output values 114, generated by ADC 112 to determine gain-error compensation coefficient 118. The gain-error compensation logic 102 determines the difference, if any, between the ADC output values 114 generated by the ADC 112 and expected ADC values that were predetermined based on the series of digital codes 104 provided to the Sigma-Delta DAC 106 and determines the gain-error compensation coefficient 118 based on the determined difference. In one or more examples, gain-error compensation logic 102 or another digital logic block, may optionally apply the determined gain-error compensation to the ADC output values generated by ADC 112 to manage gain error and ensure that the ADC 112 provides suitably accurate measurements. In one or more examples, gain-error compensation logic 102 may be implemented in hardware or firmware and may operate continuously or during calibration phases.

Sigma-Delta DAC 106 is a sigma-delta Digital-to-Analog Converter (DAC) (or a DAC equivalent to a first order sigma-delta DAC such as a Pulse Density Modulation (PDM) DAC, without limitation) that converts digital codes into analog voltage levels. The Sigma-Delta DAC 106 receives a series of digital codes 104 generated by gain-error compensation logic 102 and generates a series of equally spaced DAC output voltages based on the series of digital codes 104. Respective voltage levels of the DAC output voltages 110 serve as reference voltages for measuring the gain error of ADC 112.

Analog voltage supply 108 is one or more stable power sources that provide the voltage levels for the operation of the analog circuits of the Sigma-Delta DAC 106. In one or more examples, DAC output voltages 110 (and the digital codes 104 that produce them) are chosen to be ratiometric to the values of the supply voltages provided by analog voltage supply 108. This simplifies the comparison between the ADC output values 114 and the expected ADC values.

ADC 112 is an analog-to-digital converter that measures the analog voltage levels of DAC output voltages 110 and converts them into the digital values of ADC output values 114. The digital values of the ADC output values 114 may be used to determine the gain error of ADC 112.

Notably, the gain error determined for ADC 112 is actually the gain error of Sigma-Delta DAC 106 and ADC 112, together. As mentioned above, since the gain error characteristic of the Sigma-Delta DAC 106 is small, the gain error of the ADC 112 contributes to a comparatively large share of the determined gain error of the combined Sigma-Delta DAC 106 and ADC 112.

The spacing of the DAC output voltages 110 on which the ADC output values 114 are based correspond to N equally spaced measurement points of the ADC range. For each of the respective measurement points, the error detector 202 compares the ADC output values 114 with expected ADC output values 116 to determine discrepancies (errors).

In one or more examples, the ADC range is divided into segments, specifically, a first segment that corresponds to an upper half of the ADC range and a second segment that corresponds to a lower half of the ADC range. The N measurement points of the ADC range are divided into a set of measurement points in the lower half of the ADC range and a set of measurement points in an upper half of the range of ADC range. The system error at the measurement points (e.g., errors for lower half of operating range 212 and errors for upper half of operating range 214) in the different segments of the ADC range is accumulated and may be used to solve for various types of error, including gain error of ADC 112, as discussed below.

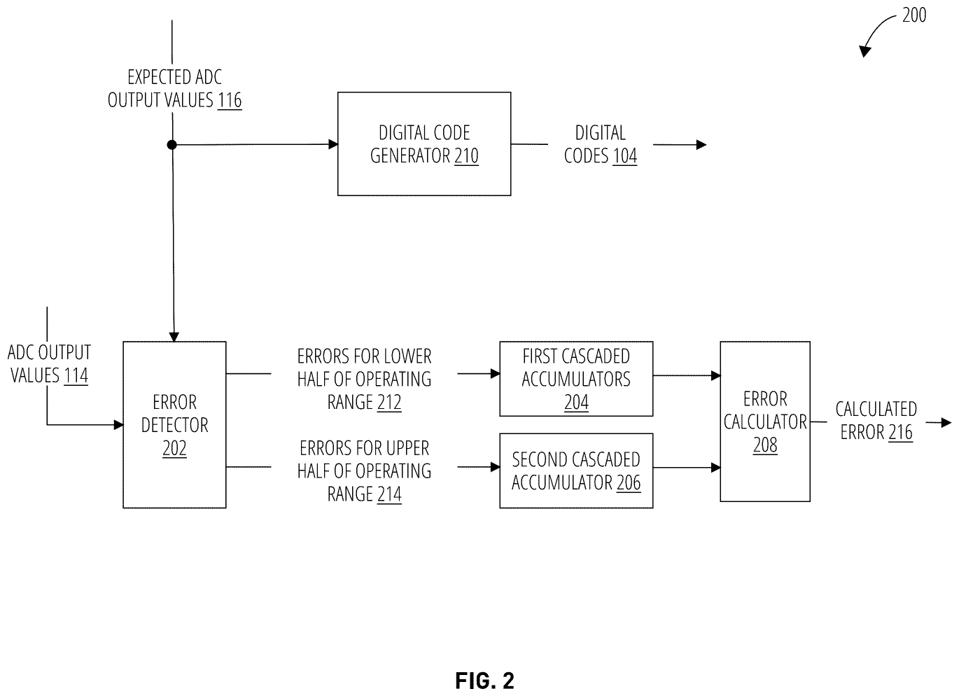

FIG. 2 is a block diagram depicting an apparatus 200 for determining gain-error compensation in accordance with one or more examples. Apparatus 200 is a non-limiting example of gain-error compensation logic 102 of FIG. 1 and may also be referred to herein as a gain-error compensation logic 200.

Gain-error compensation logic 200 includes error detector 202, first cascaded accumulators 204, second cascaded accumulators 206, error calculator 208 and digital code generator 210. In the example depicted by FIG. 2, two sets of dual cascaded accumulators 204 and 206 are depicted, a first logical set of cascaded accumulators for the errors in the lower half of the operating range, and a second logical set of cascaded accumulators for errors in the upper half of the operating range. In various examples, first and second cascaded accumulators 204 and 206 may be implemented by one or more sets of cascaded accumulators, e.g., multiple sets of cascaded accumulators respectively for errors in the various segments into which the operating range is divided, or implemented by a single set of cascaded accumulators, multiplexing in time according to the various segments into which the operating range is divided, or combinations of the same, without limitation.

Error detector 202 receives ADC output values 114 and expected ADC output values 116, and determines a difference, if any, based thereon. For respective DAC output voltages 110, error detector 202 determines the difference (error) between the expected digital output of the ADC 112 (based on the ideal conversion and represented by expected ADC output values 116) and the actual ADC output values 114. These errors are represented by the expression:

$$e [ k ] - \frac{{x}_{DAC}}{{N}_{DAC}} - \frac{{x}_{ADC}}{{N}_{ADC}} .$$

Alternatively, these errors may be represented as eᵢ=Xᵢ−Yᵢ eᵢ=xᵢ−yᵢ where X_{DAC}/N_{DAC} is the digital input value provided to the DAC normalized to the full DAC range, and X_{ADC}/NADC is the digital output value from the DAC normalized to the full ADC range.

The error e[k] or e; are the errors of a system that includes Sigma-Delta DAC 106 and ADC 112. The system's DC transfer function has a least-squares fit of piecewise linear basis functions that include a unit ramp function. The coefficient of the linear ramp function is the gain coefficient. The gain coefficient is the multiplier for the unit ramp function in the least-squares fit. It represents the actual gain of the system. If the gain coefficient differs from 1, it indicates a gain error. The gain error in the ADC 112 may also be modeled as part of a least-squares fit using piecewise linear basis functions.

Error calculator 208 determines the gain error (calculated error 216) of the ADC 112 (and optionally other types of error of the system) based on the accumulated error values at first cascaded accumulators 204 and second cascaded accumulators 206 and a system of piecewise linear basis functions. In one or more examples, error calculator 208 applies a least-squares analysis to isolate the coefficients that represent various error components, including gain error of ADC 112, and calculates the compensation needed to correct the ADC's gain error.

Regarding the processing done by the error calculator 208 to determine the various errors:

The system errors at the measurement points are modeled as functions of the normalized voltage, represented as a linear combination of the following basis functions:
ƒ₀(x): Unit offset (a constant term)
ƒ₁(x): Unit gain (a linear term)
ƒ₂(x): Unit triangle (a nonlinear term)
ƒ₃(x): Half-sign function (a discontinuous term)

The basis functions are defined as follows:

$${f}_{0} ( x ) = 1 \\ {f}_{1} ( x ) = x \\ {f}_{2} ( x ) = min ( 2 x , 2 - 2 x ) \\ {f}_{3} ( x ) = \{ \begin{matrix}1 & if x \geq 0.5 \\ - 1 & otherwise\end{matrix}$$

The errors are modeled as a linear combination of these basis functions: e(x)=a₀ƒ₀(x)+a₁ƒ₁(x)+a₂ƒ₂(x)+a₃ƒ₃(x), where:
a₀: Coefficient for offset
a₁: Coefficient for gain error
a₂: Coefficient for triangle error
a₃: Coefficient for differential offset (half-sign function)

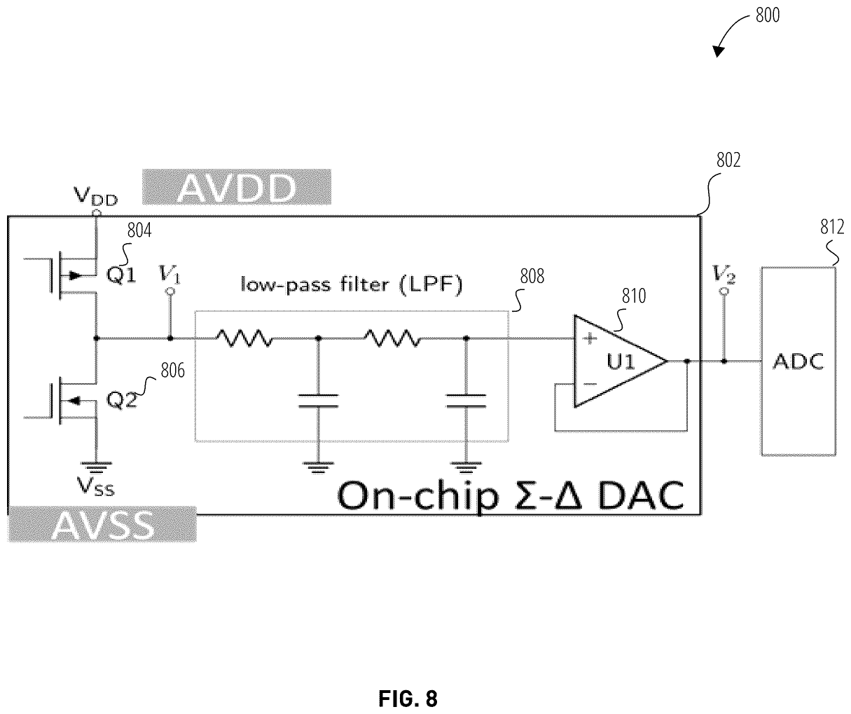

The offset (αₐ) may come from both the ADC and the DAC's op-amp. Gain Error ( ) primarily pertains to the ADC. Triangle Error ( ) is attributed to the DAC's transistor drive stage. In the case of a sigma-delta DAC this is specifically the difference in switching times between the high- and low-side drive transistors (Q1 and Q2 in FIG. 8). Differential Offset ( ) arises from the DAC buffer stage mismatch in offset voltages between N-channel and P-channel input stages.

The system errors are accumulated for different segments of the ADC range to capture the sum of the differences between the expected and actual ADC outputs. For clarity the following accumulated-error terms (here, scalers S_{1L}, S_{1R}, S_{2L}, and S_{2R}) are introduced, eᵢ [symbol] (xᵢ−yᵢ) is the instantaneous system error at the i-th sample index, i and j (or k) denote integer sample indices (k [symbol] i in single-index notation), h designates the index of the mid-range boundary (0≤i≤h≤N), and N is the total number of samples:

$${S}_{1 L} {\sum }_{\{ i = 0 \}}^{\{ h - 1 \}} {e}_{i} :$$

Accumulated error in the set of dual cascaded accumulators for the lower half of the range.

$${S}_{1 R} {\sum }_{\{ i = h \}}^{\{ N - 1 \}} {e}_{i} :$$

Accumulated error in the set of dual cascaded accumulators for the upper half of the range.

$${S}_{2 L} {\sum }_{\{ i = 0 \}}^{\{ h - 1 \}} ( h - i ) {e}_{i} :$$

Second-order accumulated error in the set of dual cascaded accumulators for the lower half of the range.

$${S}_{2 R} {\sum }_{\{ i = h \}}^{\{ N - 1 \}} ( N - i ) {e}_{i} :$$

Second-order accumulated error in the set of dual cascaded accumulators for the upper half of the range.

A system of linear equations are formed that relate the accumulated error terms S_{1L}, S_{1R}, S_{2L}, S_{2R} to the basis function coefficients a₀, a₁, a₂, a₃. Each accumulated error value may be seen as a weighted sum of the basis function contributions over a range of input values and may be expressed as:

$${S}_{1 L} = {\sum }_{i = 0}^{h - 1} ( {x}_{i} - {y}_{i} ) \\ {S}_{1 R} = {\sum }_{i = h}^{N - 1} ( {x}_{i} - {y}_{i} ) \\ {S}_{2 L} = {\sum }_{i = 0}^{h - 1} {\sum }_{j = 0}^{i} ( {x}_{j} - {y}_{j} ) \\ {S}_{2 R} = {\sum }_{i = h}^{N - 1} {\sum }_{j = h}^{i} ( {x}_{j} - {y}_{j} )$$

A least-squares problem is formulated by constructing a basis matrix B using the piecewise linear basis functions evaluated at each measurement point:

$$B = [ \begin{matrix}{f}_{0} ( {x}_{0} ) & {f}_{1} ( {x}_{0} ) & {f}_{2} ( {x}_{0} ) & {f}_{3} ( {x}_{0} ) \\ {f}_{0} ( {x}_{1} ) & {f}_{1} ( {x}_{1} ) & {f}_{2} ( {x}_{1} ) & {f}_{3} ( {x}_{1} ) \\ {f}_{0} ( {x}_{N - 1} ) & {f}_{1} ( {x}_{N - 1} ) & {f}_{2} ( {x}_{N - 1} ) & {f}_{3} ( {x}_{N - 1} )\end{matrix} ]$$

The basis matrix B is rewritten in terms of the accumulated errors, i.e., the coefficients a₀, a₁, a₂, a₃ may be expressed in terms of S_{1L}, S_{1R}, S_{2L}, S_{2R} as follows:

$${a}_{0} = f ( {S}_{1 L} , {S}_{1 R} ) \\ {a}_{1} = g ( {S}_{1 L} , {S}_{1 R} ) \\ {a}_{2} = h ( {S}_{2 L} , {S}_{2 R} ) \\ {a}_{3} = k ( {S}_{2 L} , {S}_{2 R} )$$

Functions f, g, h, and k may be expressed as:

$$f = - {S}_{1 L} + \frac{3 {S}_{2 L}}{h + 1} \\ g = 3 {S}_{1 L} + \frac{6 {S}_{2 L}}{h + 1} \\ h = - {S}_{1 R} + \frac{3 {S}_{2 R}}{h + 1} \\ k = 3 {S}_{1 R} + \frac{6 {S}_{2 R}}{h + 1}$$

The basis functions within each segment (here a half range) are composed of linear segments, so the computations may be based on accumulated error terms S_{1L}, S_{1R}, S_{2L}, and S_{2R}, without having to store and then process all the error values.

The least-squares problem is solved to obtain these coefficients. The least-squares coefficients can be expressed as: a=[a₀, a₁, a₂, a₃]:

$$a = {( {B}^{T} B )}^{- 1} {B}^{T} e$$

Once the coefficients are determined, useful coefficients may be extracted from the coefficient vector a, including the coefficient that corresponds to the gain error of the ADC.

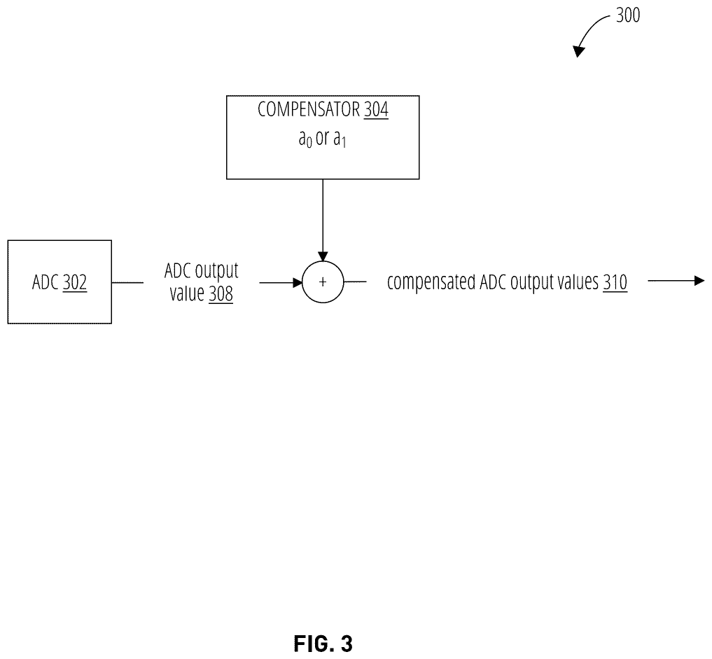

FIG. 3 is a block diagram depicting a system 300 that compensates ADC output based on offset or gain error determined in accordance with one or more examples.

System 300 includes ADC 302 and compensator 304. Compensator 304 applies offset compensation based on coefficient a₀, gain-error compensation based on coefficient a₁, or both, to ADC output value 308 to produce compensated ADC output values 310.

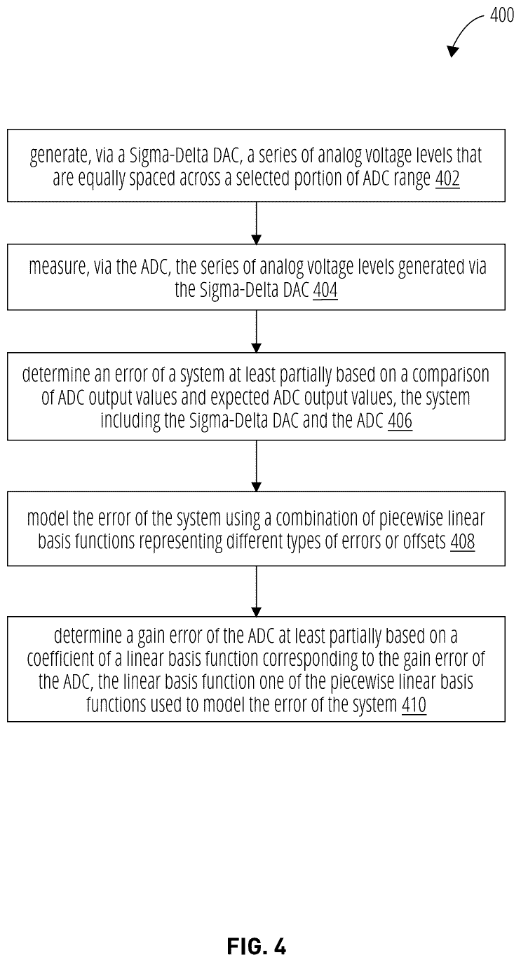

FIG. 4 is a flow diagram depicting a process 400 to determine a gain-error compensation in accordance with one or more examples. Although the example process 400 depicts a particular sequence of operations, the sequence may be altered without departing from the scope of the present disclosure. For example, some of the operations depicted may be performed in parallel or in a different sequence that does not materially affect the function of the process 400. In other examples, different components of an example device or system that implements the process 400 may perform functions at substantially the same time or in a specific sequence. In one or more examples, some or a totality of operations of process 400 may be performed by system 100 or gain-error compensation logic 200.

According to one or more examples, process 400 may include generating, via a sigma-delta DAC, a series of analog voltage levels that are equally spaced across a selected portion of the ADC range at operation 402. In one or more examples, the selected portion of the ADC range correspond to a central portion of the operating range of ADC but specifically excluding upper and lower boundaries of the operating range of the ADC. Equally spaced voltage levels exhibit uniform differences between the analog voltage levels generated by the sigma-delta DAC.

According to one or more examples, process 400 may include measuring, via the ADC, the series of analog voltage levels generated via the sigma-delta DAC at operation 404. The equally spaced voltage levels generated by the sigma-delta DAC correspond to specific measurement points within the central portion of the ADC's operating range. At each of these measurement points, the ADC samples the analog voltage level and converts it into a digital value (respectively an ADC output value). This process creates a series of measurement points that are uniformly distributed across the selected portion of the ADC's range, allowing a systematic analysis of the ADC's performance.

According to one or more examples, process 400 may include determining an error of a system at least partially based on a comparison of ADC output values and expected ADC output values, at operation 406. The system behavior of the sigma-delta DAC and the ADC is analyzed to determine the system error. By comparing the digital output values from the ADC with the expected ADC output values (which are based on the known input voltages (input to the ADC) generated by the sigma-delta DAC), discrepancies may be observed and error quantified.

According to one or more examples, process 400 may include modeling the error of the system using a combination of piecewise linear basis functions representing different types of errors or offsets at operation 408. In one or more examples, modeling the system error may include creating a mathematical model of the system error based on the observed discrepancies between expected and actual ADC output values. The system error may be represented using piecewise linear basis functions. Piecewise linear basis functions are linear segments defined over specific intervals, making them well-suited for representing linear behavior and approximating complex, non-linear behaviors in a segmented manner.

According to one or more examples, process 400 may include determining a gain error of the ADC at least partially based on a coefficient of a linear basis function corresponding to the gain error of the ADC, at operation 410. The linear basis function is one of the piecewise linear basis functions used to model the system error. When modeling the system error, each basis function is associated with a coefficient that quantifies the magnitude of that particular type of error. The gain error may be determined as the difference between 1 and the actual coefficient a₁ obtained from the error model.

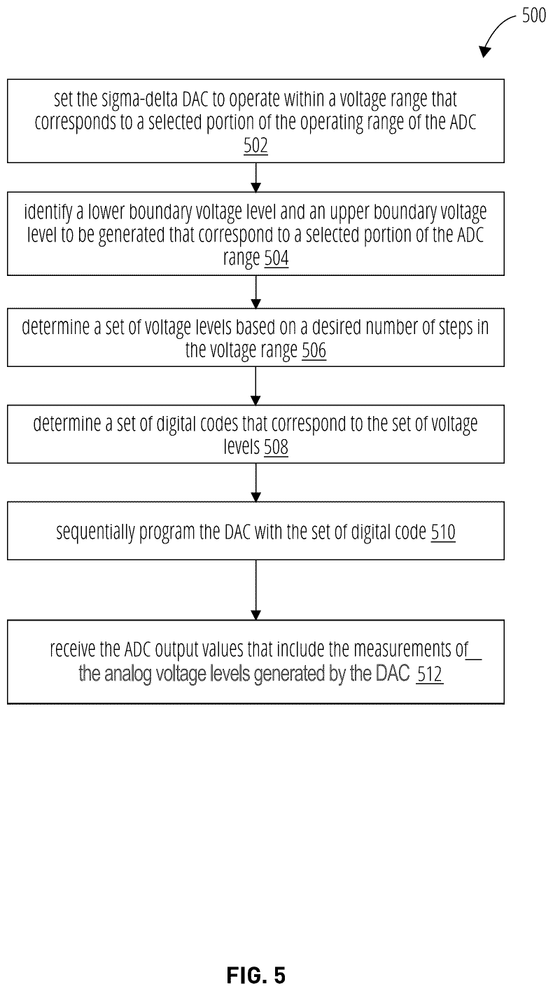

FIG. 5 is a flow diagram depicting a process 500 to generate the voltage levels that are equally spaced across a selected portion of the ADC range, in accordance with one or more examples. Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence. Some or a totality of operations of process 500 may be performed by system 100 or gain-error compensation logic 200.

According to some examples, process 500 may include setting the sigma-delta DAC to operate within a voltage range that corresponds to the operating range of the ADC at operation 502. The ADC will have a specific operating voltage range within which it can accurately convert analog signals to digital values. This range may be defined by prespecified minimum and maximum voltage levels that the ADC may handle. The sigma-delta DAC is configured to generate analog voltage levels within the same range as the ADC's operating range. This ensures that the voltages produced by the DAC can be accurately sampled and converted by the ADC. In one or more examples, the voltage range settings of the sigma-delta DAC are adjusted. This may involve setting reference voltages and scaling factors within the DAC to ensure its output voltages match the ADC's input range.

According to some examples, process 500 may include identifying a lower boundary voltage level and an upper boundary voltage level to be generated that correspond to a selected portion of the ADC range at operation 504. In one or more examples, the selected portion is the central part of the ADC's range, excluding the extreme upper and lower boundaries. In one or more examples, the lower boundary voltage level marks the starting point of the voltage levels to be generated by the DAC, and the upper boundary voltage level marks the end point of the voltage levels to be generated by the DAC, or vice-versa.

According to some examples, process 500 may include determining a set of voltage levels based on a desired number of steps in the voltage range at operation 506. The voltage range within which the DAC will generate output voltages was defined by the previously identified lower and upper boundary voltage levels. The desired number of discrete steps (N) within the specified voltage range indicates how many equally spaced voltage levels will be generated by the DAC. The step size (ΔV) is determined by dividing the total range of voltage levels to generated by the DAC by the number of steps minus one. The set of voltage levels starting from the lower boundary voltage level and adding the step size incrementally until the upper boundary voltage level is reached, or from upper boundary voltage level to lower boundary voltage level.

According to some examples, process 500 may include determining a set of digital codes that correspond to the set of voltage levels at operation 508. In one or more examples, the resolution of the DAC is determined. The resolution is typically given in bits (e.g., 10-bit, 12-bit), which determines the number of discrete levels the DAC can produce. For instance, a 12-bit DAC can produce 2¹²=4096 distinct levels. The range of voltages that the DAC will convert to digital codes is defined. It corresponds to the set of voltage levels determined in operation 506. For each voltage level in the set, the corresponding digital code is determined.

According to some examples, process 500 may include sequentially programming the DAC with the set of digital code at operation 510. In one or more examples, the set of digital codes that correspond to the desired voltage levels should be in a format for the DAC to interpret. Respective digital codes are provided to the DAC (i.e., to the DAC input) in sequence, ensuring that the DAC outputs the corresponding analog voltage level for each code in sequence.

According to some examples, the method includes receiving the ADC output values that include the measurements of the analog voltage levels generated by the DAC at operation 512.

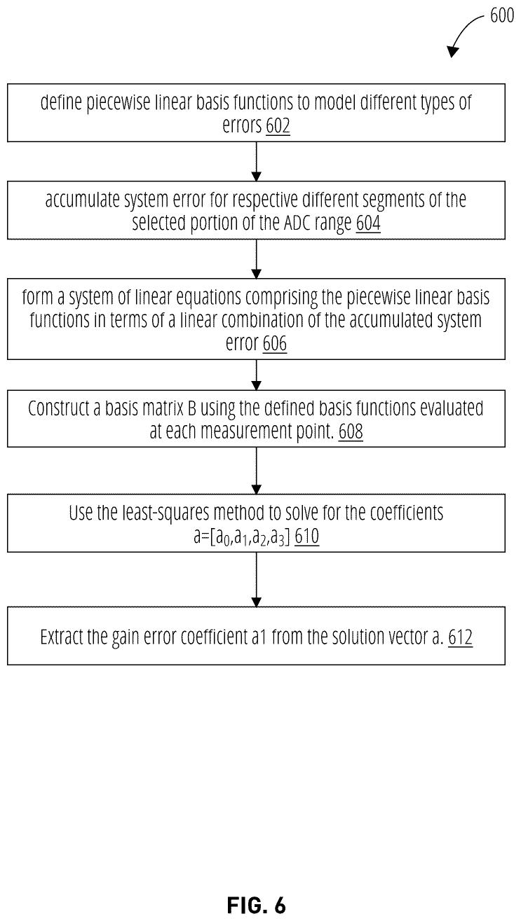

FIG. 6 is a flow diagram depicting a process 600 to determine gain error of an ADC in accordance with one or more examples. Although the example process 600 depicts a particular sequence of operations, the sequence may be altered without departing from the scope of the present disclosure. For example, some of the operations depicted may be performed in parallel or in a different sequence that does not materially affect the function of the process 600. In other examples, different components of an example device or system that implements the process 600 may perform functions at substantially the same time or in a specific sequence. Some or a totality of operations of process 600 may be performed by system 100 or gain-error compensation logic 200.

According to some examples, process 600 may include defining piecewise linear basis functions to model different types of errors at operation 602. A set of piecewise linear basis functions are defined that will be used to model different types of errors in the delta-sigma DAC and ADC system. The basis functions are mathematical constructs that can represent various types of linear behavior and approximate various types of non-linear behavior.

According to some examples, process 600 may include accumulating system error for respective different segments of the selected portion of the ADC range at operation 604. The accumulated errors at least partially quantify the overall error behavior across various segments of the selected portion of the ADC range.

According to some examples, process 600 may include forming a system of linear equations comprising the piecewise linear basis functions in terms of a linear combination of the accumulated system error at operation 606. This involves forming a system of linear equations that represent the system error as a linear combination of the defined piecewise linear basis functions. These equations incorporate the accumulated system error values, thereby relating the observed errors to the basis functions through linear equations.

According to some examples, process 600 may include constructing a basis matrix B using the defined basis functions evaluated at each measurement point at operation 608. Respective rows represent the values of the basis functions evaluated at a specific measurement points. The basis matrix B provides a structure for solving the system of linear equations using the least-squares method.

According to some examples, process 600 may include using the least-squares method to solve for the coefficients a=[a₀, a₁, a₂, a₃] at operation 610.

According to some examples, process 600 may include extracting the gain error coefficient a₁ from the solution vector a at operation 612.

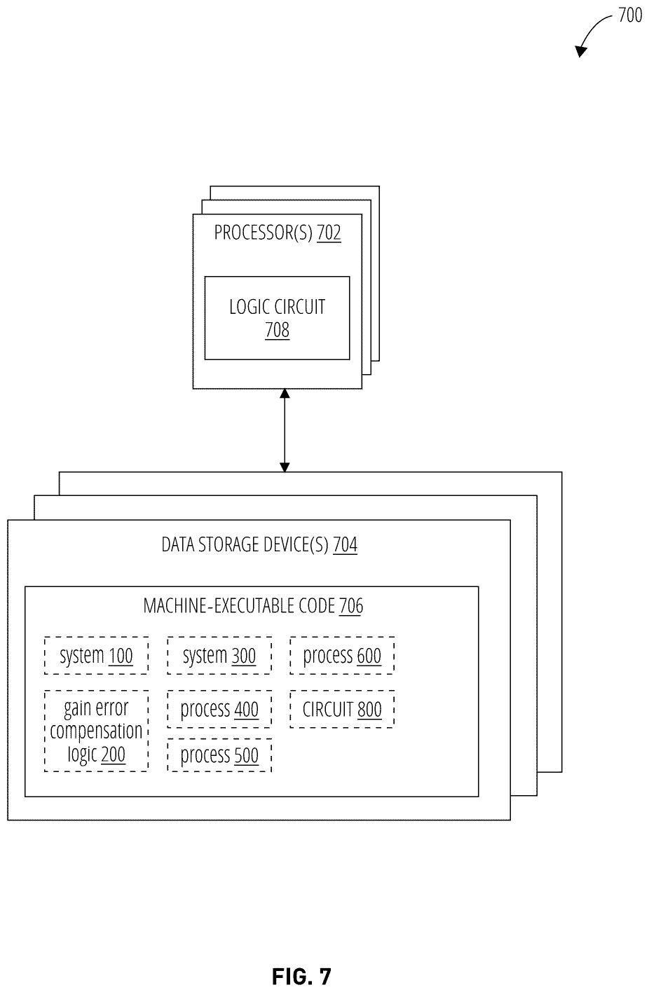

It will be appreciated by those of ordinary skill in the art that functional elements of examples disclosed herein (e.g., functions, operations, acts, processes, or methods) may be implemented in any suitable hardware, software, firmware, or combinations thereof. FIG. 7 illustrates non-limiting examples of implementations of functional elements disclosed herein. In some examples, some or all portions of the functional elements disclosed herein may be performed by hardware capable of carrying out the functional elements.

It will be appreciated by those of ordinary skill in the art that functional elements of examples disclosed herein (e.g., functions, operations, acts, processes, or methods) may be implemented in any suitable hardware, software, firmware, or combinations thereof. FIG. 7 illustrates non-limiting examples of implementations of functional elements disclosed herein. In some examples, some or all portions of the functional elements disclosed herein may be performed by hardware capable of carrying out the functional elements.

FIG. 7 is a block diagram of a circuitry 700 that, in some examples, may be used to implement various functions, operations, acts, processes, or methods disclosed herein. The circuitry 700 includes one or more processors 702 (sometimes referred to herein as “processors 702”) operably coupled to one or more data storage devices 704 (sometimes referred to herein as “storage 704”). The storage 704 includes machine-executable code 706 stored thereon and the processors 702 include logic circuit 708. The machine-executable code 706 includes information describing functional elements that may be implemented by (e.g., performed by) the logic circuit 708. The logic circuit 708 is adapted to implement (e.g., perform) the functional elements described by the machine-executable code 706. The circuitry 700, when executing the functional elements described by the machine-executable code 706, should be considered as special purpose hardware for carrying out functional elements disclosed herein. In one or more examples, the processors 702 may perform the functional elements described by the machine-executable code 706 sequentially, concurrently (e.g., on one or more different hardware platforms), or in one or more parallel process streams.

When implemented by logic circuit 708 of the processors 702, the machine-executable code 706 adapts the processors 702 to perform operations of examples disclosed herein. By way of non-limiting example, the machine-executable code 706 may adapt the processors 702 to perform some or a totality of operations of one or more of: process 400, process 500, or process 600.

Also, by way of non-limiting example, the machine-executable code 706 may adapt the processors 702 to perform some or a totality of features, functions, or operations disclosed herein for one or more of: 100, gain-error compensation logic 200, or system 300. More specifically, features, functions, or operations disclosed herein for one or more of: a sigma-delta DAC 106, an analog voltage supply 108, an ADC 112, and a gain-error compensation logic 102 of system 100; or error detector 202, first cascaded accumulators 204, second cascaded accumulator 206, error calculator 208 and digital code generator 210 of gain-error compensation logic 200.

The processors 702 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose computer including one or more processors 702, including a general-purpose processor, is considered a special-purpose computer at least while the general-purpose computer executes functional elements corresponding to the machine-executable code 706 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 702 may include any conventional processor, controller, microcontroller, or state-machine. An FPGA or other PLD of the processors 702 may be configured (e.g., programmed, without limitation) with configuration data to perform functions disclosed herein, or, additionally or alternatively, may be capable of being configured or re-configured (e.g., programmable or re-programmable, without limitation) with configuration data to perform functions disclosed herein. The processors 702 may also be implemented as a combination of computing devices, such as a combination of a DSP and a microprocessor, a plurality of microprocessors, one or more microprocessors in conjunction with a DSP core, or any other such configuration.

In one or more examples the storage 704 includes volatile data storage (e.g., random-access memory (RAM), static RAM (SRAM), without limitation), non-volatile data storage (e.g., Flash memory, a hard disc drive, a solid-state drive, erasable programmable read-only memory (EPROM), without limitation). In some examples the processors 702 and the storage 704 may be implemented into a single device (e.g., a semiconductor device product, a system on chip (SOC), without limitation). In some examples the processors 702 and the storage 704 may be implemented into separate devices.

In one or more examples the machine-executable code 706 may include computer-readable instructions (e.g., software code, firmware code). By way of non-limiting example, the computer-readable instructions may be stored by the storage 704, accessed directly by the processors 702, and executed by the processors 702 using at least the logic circuit 708. Also, by way of non-limiting example, the computer-readable instructions may be stored on the storage 704, transferred to a memory device (not shown) for execution, and executed by the processors 702 using at least the logic circuit 708. Processors 702 or logic circuit 708 thereof be coupled to such a memory device or include such a memory device (e.g., a configuration memory cell, without limitation). Accordingly, in some examples the logic circuit 708 includes electrically configurable logic circuit 708.

In one or more examples the machine-executable code 706 may describe hardware (e.g., circuitry) to be implemented in the logic circuit 708 to perform the functional elements. This hardware may be described at any of a variety of levels of abstraction, from low-level transistor layouts to high-level description languages. At a high level of abstraction, a hardware description language (HDL) such as an IEEE Standard hardware description language (HDL) may be used. By way of non-limiting examples, Verilog, SystemVerilog or very-large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 708 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine-executable code 706 may include an HDL, an RTL, a GL description, a mask level description, other hardware description, or any combination thereof.

In examples where the machine-executable code 706 includes a hardware description (at any level of abstraction), a system (not shown, but including the storage 704) implements the hardware description described by the machine-executable code 706. By way of non-limiting example, the processors 702 may include a programmable logic device (e.g., an FPGA or a PLC, without limitation) and the logic circuit 708 may be electrically controlled (e.g., via configuration data, without limitation) to implement circuitry corresponding to the hardware description into the logic circuit 708. Also, by way of non-limiting example, the logic circuit 708 may include hard-wired logic manufactured by a manufacturing system (not shown, but including the storage 704) according to the hardware description of the machine-executable code 706.

Regardless of whether the machine-executable code 706 includes computer-readable instructions or a hardware description, the logic circuit 708 is adapted to perform the functional elements described by the machine-executable code 706 when implementing the functional elements of the machine-executable code 706. It is noted that although a hardware description may not directly describe functional elements, a hardware description indirectly describes functional elements that the hardware elements described by the hardware description are capable of performing.

FIG. 8 is a schematic diagram depicting an on-chip sigma-delta digital-to-analog converter (E-A DAC) signal path 800 that is exercised during the gain-error-calibration routine described above with reference to FIGS. 3-6. The E-A DAC is fabricated on the same mixed-signal die as the remainder of the analog front end and is biased between the analog supply rails AVDD and AVSS to ensure ratiometric operation with the analog-to-digital converter (ADC) 816.

Within the E-A DAC block 802, complementary output transistors Q1 804 (high-side NMOS) and Q2 806 (low-side NMOS) are driven by a first-order sigma-delta modulator (not shown) so as to steer charge between AVDD and AVSS. The resulting single-bit pulse-density bit-stream appears at node V1.

A low-pass filter (LPF) 808 (here, a three-section resistor-capacitor ladder) averages the bit-stream, converting it into a substantially DC output-voltage level at node V1. Because the LPF occupies the same die area and shares process parameters with Q1/Q2, process-voltage-temperature (PVT) tracking is ensured.

A rail-to-rail operational amplifier U1 810, configured as a unity-gain follower, isolates the Σ-Δ DAC 802 from the sampling network of the ADC 812 while preserving the ratiometric relationship to AVDD/AVSS. The buffer drives node V2, which is connected directly to the differential input of the ADC 812.

During a calibration cycle the gain-error-compensation logic (see FIG. 3, block 330) commands the Σ-Δ DAC 802 to step through multiple, uniformly spaced digital codes. Each code produces a corresponding DC voltage level at note V2 that the ADC 812 digitizes. The system error is computed as the difference between the resulting ADC output value and a pre-computed expected value, and is subsequently accumulated into the first- and second-order scalars S_{1L}, S_{1R}, S_{2L}, and S_{2R}.

Physical sources of higher-order error components may include a mismatch in the switching delay of transistors and/or offset-voltage asymmetry. A mismatch in the switching delay of transistors Q1 804 and Q2 806 introduces a small curvature in the DAC transfer function; this curvature manifests as the triangle-error component captured by the unit-triangle basis function ƒ₂(x) discussed herein. Offset-voltage asymmetry between the P-channel and N-channel input pairs of buffer U1 810 causes a step change at mid-range; this step corresponds to the half-sign basis function ƒ₃(x). The depiction by FIG. 8 enables a clear mapping from circuit-level non-idealities to the piecewise-linear error model used to extract the gain-error coefficient a₁.

Example circuit 800 of an on-chip signal path that is exercised during a gain-error-calibration process, in accordance with one or more examples. It locates all elements that contribute to the error model introduced earlier—namely, the Σ-Δ DAC's complementary output transistors Q1/Q2, the passive low-pass filter, the rail-to-rail buffer amplifier U1, and the connection into the ADC input node. By showing those elements inside a single analog supply envelope (AVDD/AVSS) and within the heavy outline labelled “On-chip Σ-Δ DAC,” the figure demonstrates (i) that the DAC can be driven ratiometrically to the same supply that biases the ADC, and (ii) that the calibration loop is closed entirely on-chip, requiring no external precision components.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: an analog-to-digital converter (ADC); a sigma-delta digital-to-analog-converter (DAC); and a gain-error compensation logic to: control the sigma-delta DAC to generate DC output voltages within a selected portion of the operating range of the ADC; determine an error of the system at least partially based on a comparison of expected ADC output values and ADC output values generated by the ADC in response to the generated DC output voltages; model the error of the system using a combination of piecewise linear basis functions representing different types of errors or offsets; and determine a gain error of the ADC at least partially based on a coefficient of a linear basis function corresponding to the gain error of the ADC, the linear basis function one of the piecewise linear basis functions used to model the error of the system.

Example 2: The apparatus according to Example 1, wherein to control the sigma-delta DAC to generate DC output voltages within the selected portion of the operating range of the ADC, the gain-error compensation logic to: command the DAC to generate substantially DC output-voltage levels uniformly spaced across a selected portion of an input-voltage range of the ADC.

Example 3: The apparatus according to any of Examples 1 and 2, wherein the gain-error compensation logic to: determine, for respective output-voltage levels, a difference between an expected ADC code value and an ADC code value produced by the ADC in response to a respective output-voltage level; and use the determined difference in the comparison of expected ADC output values and ADC output values generated by the ADC in response to the generated DC output voltages.

Example 4: The apparatus according to any of Examples 1 through 3, wherein the combination of piecewise linear basis functions representing different types of errors or offsets includes piecewise linear basis functions respectively representing offset error, gain error, or a higher-order error component that captures non-ideal behavior.

Example 5: The apparatus according to any of Examples 1 through 4, wherein the higher-order error component that captures non-ideal behavior is: a triangle error component represented by a unit-triangle basis function, the triangle error attributable to timing mismatch between high-side and low-side drive transistors of the sigma-delta DAC, or a differential-offset error component represented by a half-sign basis function, the differential-offset error attributable to offset-voltage mismatch between P-channel and N-channel input stages of a buffer stage of the sigma-delta DAC.

Example 6: The apparatus according to any of Examples 1 through 5, wherein the gain-error-compensation logic to accumulate system-error values into first-order scalars S_{1L} and S_{1R} and second-order scalars S_{2L} and S_{2R}, each scalar corresponding to a respective lower-range or upper-range half of the selected portion of the ADC input-voltage range.

Example 7: The apparatus according to any of Examples 1 through 6, wherein the gain-error-compensation logic to determine the coefficient of the linear basis function by solving a least-squares normal equation expressed exclusively in terms of the scalars S_{1L}, S_{1R}, S_{2L}, and S_{2R}.

Example 8: The apparatus according to any of Examples 1 through 7, comprising a calibration register to store the determined gain-error value, and wherein the gain-error-compensation logic to apply a gain-compensation factor derived from the calibration register to subsequent ADC output values generated during normal operation.

Example 9: The apparatus according to any of Examples 1 through 8, wherein the selected portion of the input-voltage range spans approximately one-half of a full-scale input range of the ADC.

Example 10: The apparatus according to any of Examples 1 through 9, wherein the sigma-delta DAC and the ADC are monolithically integrated on a common semiconductor die.

Example 11: A method comprising: generating, via a sigma-delta DAC, a series of analog voltage levels that are equally spaced across a selected portion of ADC range; measuring, via the ADC, the series of analog voltages levels generated via the sigma-delta DAC; determining an error of a system at least partially based on a comparison of ADC output values and expected ADC output values, the system including the sigma-delta DAC and the ADC; modeling the error of the system using a combination of piecewise linear basis functions representing different types of errors or offsets; and determining a gain error of the ADC at least partially based on a coefficient of a linear basis function corresponding to the gain error of the ADC, the linear basis function one of the piecewise linear basis functions used to model the error of the system.

Example 12: The method according to Example 11, wherein generating the series of analog-voltage levels comprises: commanding the sigma-delta DAC to output substantially DC voltage levels that are uniformly spaced across the selected portion of the ADC input-voltage range.

Example 13: The method according to any of Examples 11 and 12, comprising: determining, for each generated analog-voltage level, a difference between (i) an expected ADC code value for the respective analog-voltage level and (ii) an ADC code value produced by the ADC in response to the respective analog-voltage level, and using the determined differences in the comparison of expected and measured ADC output values.

Example 14: The method according to any of Examples 11 through 13, wherein the combination of piece-wise-linear basis functions includes basis functions respectively representing offset error, gain error, and at least one higher-order error component.

Example 15: The method according to any of Examples 11 through 14, wherein the higher-order error component comprises: a triangle-error component represented by a unit-triangle basis function, the triangle error attributable to timing mismatch between high-side and low-side drive transistors of the sigma-delta DAC; or a differential-offset error component represented by a half-sign basis function, the differential-offset error attributable to offset-voltage mismatch between P-channel and N-channel input stages of a buffer stage of the sigma-delta DAC.

Example 16: The method according to any of Examples 11 through 15, comprising: accumulating the system-error values into first-order scalars S₁L and S₁R and second-order scalars S₂L and S₂R, each scalar corresponding to a respective lower-range or upper-range half of the selected portion of the ADC input-voltage range.

Example 17: The method according to any of Examples 11 through 16, comprising: solving a least-squares normal equation that is expressed exclusively in terms of the scalars S₁L, S₁R, S₂L, and S₂R to obtain the coefficient of the linear basis function corresponding to the gain error of the ADC.

Example 18: The method according to any of Examples 11 through 17, comprising: storing the determined gain-error value in a calibration register; and applying, during subsequent normal operation, a gain-compensation factor derived from the calibration register to ADC output values generated in response to input signals.

Example 19: The method according to any of Examples 11 through 18, wherein the selected portion of the ADC input-voltage range spans approximately one-half of a full-scale input range of the ADC.

Example 20: The method according to any of Examples 11 through 19, wherein the sigma-delta DAC and the ADC are monolithically integrated on a common semiconductor die.

Example 21: A system or apparatus, comprising: at least one processor; and a memory to store instructions that, upon execution by the at least one processor, to enable the processor to: (a) command a sigma-delta digital-to-analog converter (DAC) to generate multiple substantially-DC analog-voltage levels that are uniformly spaced across a selected portion of an input-voltage range of an analog-to-digital converter (ADC) coupled to digitize an output of the sigma-delta DAC; (b) determine, for respective analog-voltage levels, a system-error value based at least in part on a comparison between an expected ADC output value for the analog-voltage level and a corresponding ADC output value produced by the ADC in response to the DC output analog-voltage level generated by the sigma-delta DAC; (c) model the system-error values as a weighted combination of predefined piece-wise-linear basis functions that respectively represent offset error, gain error, and one or more higher-order error components; and (d) determine a gain-error value of the ADC at least partially from a coefficient associated with the gain-error basis function of the weighted combination.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
an analog-to-digital converter (ADC);
a sigma-delta digital-to-analog-converter (DAC); and
a gain-error compensation logic to:
control the sigma-delta DAC to generate DC output voltages within a selected portion of the operating range of the ADC;
determine an error of the system at least partially based on a comparison of expected ADC output values and ADC output values generated by the ADC in response to the generated DC output voltages;
model the error of the system using a combination of piecewise linear basis functions representing different types of errors or offsets; and
determine a gain error of the ADC at least partially based on a coefficient of a linear basis function corresponding to the gain error of the ADC, the linear basis function one of the piecewise linear basis functions used to model the error of the system.

2. The apparatus of claim 1, wherein to control the sigma-delta DAC to generate DC output voltages within the selected portion of the operating range of the ADC, the gain-error compensation logic to:
command the DAC to generate substantially DC output-voltage levels uniformly spaced across a selected portion of an input-voltage range of the ADC.

3. The apparatus of claim 2, wherein the gain-error compensation logic to:
determine, for respective output-voltage levels, a difference between an expected ADC code value and an ADC code value produced by the ADC in response to a respective output-voltage level; and
use the determined difference in the comparison of expected ADC output values and ADC output values generated by the ADC in response to the generated DC output voltages.

4. The apparatus of claim 1, wherein the combination of piecewise linear basis functions representing different types of errors or offsets includes piecewise linear basis functions respectively representing offset error, gain error, or a higher-order error component that captures non-ideal behavior.

5. The apparatus of claim 4, wherein the higher-order error component that captures non-ideal behavior is:
a triangle error component represented by a unit-triangle basis function, the triangle error attributable to timing mismatch between high-side and low-side drive transistors of the sigma-delta DAC, or
a differential-offset error component represented by a half-sign basis function, the differential-offset error attributable to offset-voltage mismatch between P-channel and N-channel input stages of a buffer stage of the sigma-delta DAC.

6. The apparatus of claim 1, wherein the gain-error-compensation logic to accumulate system-error values into first-order scalars S_{1L} and S_{1R} and second-order scalars S_{2L} and S_{2R}, each scalar corresponding to a respective lower-range or upper-range half of the selected portion of the ADC input-voltage range.

7. The apparatus of claim 6, wherein the gain-error-compensation logic to determine the coefficient of the linear basis function by solving a least-squares normal equation expressed exclusively in terms of the scalars S_{1L}, S_{1R}, S_{2L}, and S_{2R}.

8. The apparatus of claim 1, comprising a calibration register to store the determined gain-error value, and wherein the gain-error-compensation logic to apply a gain-compensation factor derived from the calibration register to subsequent ADC output values generated during normal operation.

9. The apparatus of claim 1, wherein the selected portion of the input-voltage range spans approximately one-half of a full-scale input range of the ADC.

10. The apparatus of claim 1, wherein the sigma-delta DAC and the ADC are monolithically integrated on a common semiconductor die.

11. A method comprising:
generating, via a sigma-delta DAC, a series of analog voltage levels that are equally spaced across a selected portion of ADC range;
measuring, via the ADC, the series of analog voltages levels generated via the sigma-delta DAC;
determining an error of a system at least partially based on a comparison of ADC output values and expected ADC output values, the system including the sigma-delta DAC and the ADC;
modeling the error of the system using a combination of piecewise linear basis functions representing different types of errors or offsets; and
determining a gain error of the ADC at least partially based on a coefficient of a linear basis function corresponding to the gain error of the ADC, the linear basis function one of the piecewise linear basis functions used to model the error of the system.

12. The method of claim 11, wherein generating the series of analog-voltage levels comprises:
commanding the sigma-delta DAC to output substantially DC voltage levels that are uniformly spaced across the selected portion of the ADC input-voltage range.

13. The method of claim 12, comprising:
determining, for each generated analog-voltage level, a difference between (i) an expected ADC code value for the respective analog-voltage level and (ii) an ADC code value produced by the ADC in response to the respective analog-voltage level, and
using the determined differences in the comparison of expected and measured ADC output values.

14. The method of claim 11, wherein the combination of piece-wise-linear basis functions includes basis functions respectively representing offset error, gain error, and at least one higher-order error component.

15. The method of claim 14, wherein the higher-order error component comprises:
a triangle-error component represented by a unit-triangle basis function, the triangle error attributable to timing mismatch between high-side and low-side drive transistors of the sigma-delta DAC; or
a differential-offset error component represented by a half-sign basis function, the differential-offset error attributable to offset-voltage mismatch between P-channel and N-channel input stages of a buffer stage of the sigma-delta DAC.

16. The method of claim 11, comprising:
accumulating the system-error values into first-order scalars S₁L and S₁R and second-order scalars S₂L and S₂R, each scalar corresponding to a respective lower-range or upper-range half of the selected portion of the ADC input-voltage range.

17. The method of claim 16, comprising:
solving a least-squares normal equation that is expressed exclusively in terms of the scalars S₁L, S₁R, S₂L, and S₂R to obtain the coefficient of the linear basis function corresponding to the gain error of the ADC.

18. The method of claim 11, comprising:
storing the determined gain-error value in a calibration register; and
applying, during subsequent normal operation, a gain-compensation factor derived from the calibration register to ADC output values generated in response to input signals.

19. The method of claim 11,
wherein the selected portion of the ADC input-voltage range spans approximately one-half of a full-scale input range of the ADC.

20. The method of claim 11,
wherein the sigma-delta DAC and the ADC are monolithically integrated on a common semiconductor die.

21. A system or apparatus, comprising:
at least one processor; and
a memory to store instructions that, upon execution by the at least one processor, to enable the processor to:
command a sigma-delta digital-to-analog converter (DAC) to generate multiple substantially-DC analog-voltage levels that are uniformly spaced across a selected portion of an input-voltage range of an analog-to-digital converter (ADC) coupled to digitize an output of the sigma-delta DAC;
determine, for respective analog-voltage levels, a system-error value based at least in part on a comparison between an expected ADC output value for the analog-voltage level and a corresponding ADC output value produced by the ADC in response to the DC output analog-voltage level generated by the sigma-delta DAC;
model the system-error values as a weighted combination of predefined piece-wise-linear basis functions that respectively represent offset error, gain error, and one or more higher-order error components; and
determine a gain-error value of the ADC at least partially from a coefficient associated with the gain-error basis function of the weighted combination.
